(19) United States
(12) Patent Application Publication
(10) Pub. No.: US 2026/0076224 A1
(43) Pub. Date: Mar. 12, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: SANG CHEON PARK, Suwon-si (KR); UN-BYOUNG KANG, Suwon-si (KR); KUYOUNG KIM, Suwon-si (KR); JUNWOO MYUNG, Suwon-si (KR); JEONGHWAN PARK, Suwon-si (KR); SEUNG-JIN LEE, Suwon-si (KR)

(21) Appl. No.: 19/176,331

(22) Filed: Apr. 11, 2025

(30) Foreign Application Priority Data
Sep. 10, 2024 (KR) 10-2024-0123159

(51) Int. Cl. H01L 23/538; H01L 21/48; H01L 23/00; H01L 23/367; H01L 23/498; H01L 25/18; H10B 80/00; H10D 80/30

(52) U.S. Cl. CPC H10W 70/611; H10W 70/65; H10W 70/685; H10W 70/69; H10W 90/00; H10W 90/401; H10B 80/00; H10D 80/30; H10W 40/22; H10W 70/05; H10W 72/0198; H10W 72/884; H10W 80/312; H10W 80/327; H10W 90/288; H10W 90/297; H10W 90/734; H10W 90/754; H10W 90/792; H10W 90/794

(57) ABSTRACT

A semiconductor package includes a package substrate including first and second interconnection layers sequentially stacked and a first semiconductor device on the package substrate. The first interconnection layer includes first and second lower insulating layers sequentially stacked and a first interconnection line on the second lower insulating layer, the second interconnection layer includes first and second inorganic insulating layers sequentially stacked and a first connection pad in the second inorganic insulating layer, and the first semiconductor device includes a third inorganic insulating layer at a bottom of the first semiconductor device and contacting the second inorganic insulating layer and a second connection pad in the third inorganic insulating layer and contacting the first connection pad. The first and second lower insulating layers are formed of different materials from the first and second inorganic insulating layers, and the first inorganic insulating layer contacts a sidewall and upper surface of the first interconnection line.

### CROSS-REFERENCE TO RELATED APPLICATIONS

This U.S. non-provisional patent application claims priority under 35 U.S.C. §119 of Korean Patent Application No. 10-2024-0123159, filed on Sep. 10, 2024, the entire contents of which are hereby incorporated by reference.

### BACKGROUND

The present disclosure herein relates to a semiconductor package and a method of manufacturing the same.

An integrated circuit chip is packaged into a semiconductor package to have a suitable form to be installed in an electronic device. In general, in a semiconductor package, a semiconductor die is mounted on a printed circuit board (PCB), and the semiconductor die and the PCB are electrically connected to each other using bonding wires or bumps. With the development of the electronics industry, various research is being carried out to improve the reliability and durability of semiconductor packages.

### SUMMARY

The present disclosure provides examples of a highly integrated semiconductor package with improved heat dissipation characteristics.

The present disclosure also provides examples of a method of manufacturing a semiconductor package capable of improving yield.

The purposes of the present disclosure are not limited to the above-mentioned benefits, and other purposes not mentioned would be clearly understood by those skilled in the art from the disclosure below.

An embodiment of the inventive concept provides a semiconductor package including: a package substrate including a first interconnection layer and a second interconnection layer sequentially stacked; and a first semiconductor device disposed on the package substrate, wherein the first interconnection layer includes first and second lower insulating layers sequentially stacked and a first interconnection line disposed on the second lower insulating layer, the second interconnection layer includes first and second inorganic insulating layers sequentially stacked and a first connection pad disposed in the second inorganic insulating layer, and the first semiconductor device includes a third inorganic insulating layer disposed at a lower end of the first semiconductor device and contacting the second inorganic insulating layer and a second connection pad disposed in the third inorganic insulating layer and contacting the first connection pad, wherein the first and second lower insulating layers are formed of different materials from those of the first and second inorganic insulating layers, and the first inorganic insulating layer is in contact with a side surface and upper surface of the first interconnection line.

In an embodiment, a semiconductor package includes: a lower substrate; a redistribution layer on the lower substrate; and a first semiconductor device and a second semiconductor device arranged on the redistribution layer and spaced apart from each other, wherein the lower substrate includes first and second lower insulating layers sequentially stacked and a first interconnection line disposed on the second lower insulating layer, the redistribution layer includes first and second inorganic insulating layers sequentially stacked and a first connection pad and a second connection pad arranged in the second inorganic insulating layer and spaced apart from each other, the first semiconductor device includes a third inorganic insulating layer disposed at a lower end of the first semiconductor device and contacting the second inorganic insulating layer and a third connection pad disposed in the third inorganic insulating layer and contacting the first connection pad, and the second semiconductor device includes a fourth inorganic insulating layer disposed at a lower end of the second semiconductor device and contacting the second inorganic insulating layer and a fourth connection pad disposed in the fourth inorganic insulating layer and contacting the second connection pad, wherein the first and second lower insulating layers are formed of different materials from those of the first and second inorganic insulating layers, and the first inorganic insulating layer contacts a side surface and upper surface of the first interconnection line.

In an embodiment, a semiconductor package includes: a lower substrate; external connection terminals bonded to a lower portion of the lower substrate; a redistribution layer on the lower substrate; and a first semiconductor device and a second semiconductor device arranged on the redistribution layer and horizontally spaced apart from each other, wherein the lower substrate includes first and second lower insulating layers sequentially stacked and a first interconnection line disposed on the second lower insulating layer, the redistribution layer includes first and second inorganic insulating layers sequentially stacked and a first connection pad and a second connection pad arranged in the second inorganic insulating layer and horizontally spaced apart from each other, the first semiconductor device includes a third inorganic insulating layer disposed at a lower end of the first semiconductor device and contacting the second inorganic insulating layer and a third connection pad disposed in the third inorganic insulating layer and contacting the first connection pad, and the second semiconductor device includes a fourth inorganic insulating layer disposed at a lower end of the second semiconductor device and contacting the second inorganic insulating layer and a fourth connection pad disposed in the fourth inorganic insulating layer and contacting the second connection pad, wherein the first and second lower insulating layers are formed of different materials from those of the first and second inorganic insulating layers, an upper surface of the second inorganic insulating layer has a surface roughness of an amount greater than 0 Å to 10 Å, the second lower insulating layer has a first vertical thickness, and the first inorganic insulating layer has a second vertical thickness less than the first vertical thickness.

In an embodiment, a method of manufacturing a semiconductor package includes: forming a first interconnection part; forming a second interconnection part on the first interconnection part; and mounting a semiconductor device on the second interconnection part, wherein the forming of the second interconnection part includes: forming a first inorganic insulating layer on the first interconnection part; forming a first interconnection line on the first inorganic insulating layer; forming a second inorganic insulating layer covering the first interconnection line and the first inorganic insulating layer; and forming a first connection pad in the second inorganic insulating layer, wherein the semiconductor device includes a third inorganic insulating layer disposed on a lower surface thereof and a second connection pad disposed in the third inorganic insulating layer, and the mounting of the semiconductor device includes bonding the third inorganic insulating layer to the second inorganic insulating layer and, at the same time, connecting the second connection pad to the first connection pad by performing a thermal compression process.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of a semiconductor package according to embodiments of the inventive concept;

FIG. 2 is an enlarged view of portion P1 of FIG. 1 according to embodiments of the inventive concept;

FIG. 3 is a cross-sectional view of a semiconductor package according to embodiments of the inventive concept;

FIG. 4 is a cross-sectional view of a semiconductor package according to embodiments of the inventive concept;

FIG. 5 is a cross-sectional view of a semiconductor package according to embodiments of the inventive concept;

FIG. 6 is a cross-sectional view of a semiconductor package according to embodiments of the inventive concept;

FIG. 7 is a cross-sectional view of a semiconductor package according to embodiments of the inventive concept;

FIGS. 8A to 8G are cross-sectional views illustrating a process of manufacturing the package substrate of the semiconductor package of FIG. 1, according to embodiments of the inventive concept;

FIGS. 9A to 9F are cross-sectional views illustrating a process of manufacturing the package substrate of the semiconductor package of FIG. 2, according to embodiments of the inventive concept; and

FIGS. 10A and 10B are cross-sectional views illustrating a process of manufacturing the semiconductor package of FIG. 1, according to embodiments of the inventive concept.

### DETAILED DESCRIPTION

Hereinafter, embodiments according to the inventive concept will be described in detail with reference to the drawings in order to describe the inventive concept in more detail. Herein, the terms indicating order, such as first, second, etc., are used to distinguish elements having the same/similar functions, and the ordinal numbers may be interchanged according to the order in which the terms are mentioned. These ordinal numbers may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal wiring or via to which it is connected) to promote an electrical connection to a further terminal, such as a bump or solder ball, and/or an external wiring. A pad that is hybrid bonded to another pad may be form a structure with the other pad to form a hybrid-bonded pad structure that includes two pads merged as a single pad structure.

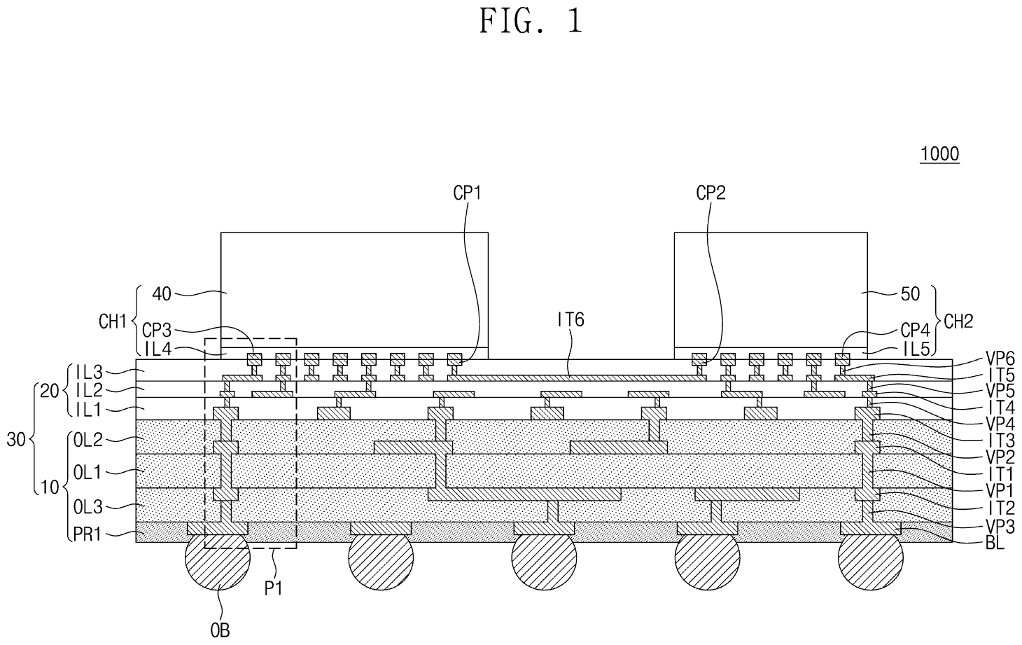

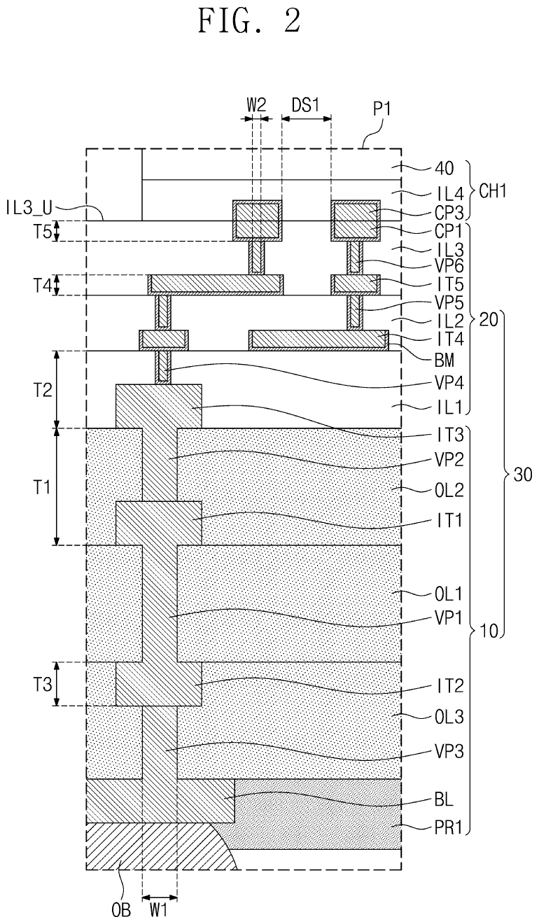

FIG. 1 is a cross-sectional view of a semiconductor package according to embodiments of the inventive concept. FIG. 2 is an enlarged view of portion P1 of FIG. 1 according to embodiments of the inventive concept.

Referring to FIGS. 1 and 2, a semiconductor package 1000 according to the present example may include a package substrate 30 and a first semiconductor device CH1 and a second semiconductor device CH2 mounted on the package substrate 30. Only one of the first semiconductor device CH1 and the second semiconductor device CH2 may be mounted on the package substrate 30. Three or more semiconductor devices may be mounted on the package substrate 30. The package substrate 30 may include a first interconnection part 10 and a second interconnection part 20 sequentially stacked. The first interconnection part 10 may be an interconnection layer including a plurality of sub-layers, and may be a lower substrate. The second interconnection part 20 may be an interconnection layer including a plurality of sub-layers and may a redistribution layer.

The first interconnection part 10 may have a structure that is the same as or similar to a structure of a double-sided or multi-layer printed circuit board. The first interconnection part 10 may include first to third lower insulating layers OL1 to OL3 and a first photo solder resist film PR1, also described as a photoresist film. Although three lower insulating layers OL1 to OL3 are described in the present example, the number of lower insulating layers is not limited thereto and may be one or at least five. In the present disclosure, a lower insulating layer may be an organic layer, polymer layer, or resin layer. The first to third lower insulating layers OL1 to OL3 include a material different than inorganic insulating layers IL1 to IL5.

The second lower insulating layer OL2 may be disposed above the first lower insulating layer OL1, and the third lower insulating layer OL3 may be disposed below the first lower insulating layer OL1. The first lower insulating layer OL1 may also be referred to as a core layer. The first to third lower insulating layers OL1 to OL3 may each be formed of epoxy resin, thermosetting resin, polyimide, thermoplastic resin, photocurable resin or prepreg. All of the first to third lower insulating layers OL1 to OL3 may be formed of the same material as each other, or different layers of the first to third lower insulating layers OL1 to OL3 may be formed of different materials from each other. The first to third lower insulating layers OL1 to OL3 may each be impregnated with a reinforcing material. The reinforcing material may be at least one of a glass fiber or an inorganic filler. Therefore, the first to third lower insulating layers OL1 to OL3 may each include at least one of a glass fiber or an inorganic filler. The first photo solder resist film PR1 is disposed under the third lower insulating layer OL3. The first photo solder resist film PR1 may be a photosensitive film. The first photo solder resist film PR1 may exclude the reinforcing material.

The first interconnection part 10 may further include first to third interconnection lines IT1 to IT3, first to third vias VP1 to VP3, and ball lands BL. In some embodiments, the first to third interconnection lines IT1 to IT3, the first to third vias VP1 to VP3, and the ball lands BL may include the same conductive material as each other, such as copper, for example. The first to third interconnection lines IT1 to IT3, the first to third vias VP1 to VP3, and the ball lands BL may be respectively in contact with the first to third lower insulating layers OL1 to OL3.

The first interconnection lines IT1 may be arranged on an upper surface of the first lower insulating layer OL1. The second interconnection lines IT2 may be arranged on a lower surface of the first lower insulating layer OL1. The first vias VP1 may penetrate the first lower insulating layer OL1. The first vias VP1 may connect some of the first interconnection lines IT1 to some of the second interconnection lines IT2, respectively. Each first via VP1, first interconnection line IT1, and second interconnection line IT2 connected to each other may have no boundary surface therebetween and may be integrated with each other as a single unitary structure.

The third interconnection lines IT3 may be arranged on the second lower insulating layer OL2. The second vias VP2 may penetrate the second lower insulating layer OL2 and may connect some of the third interconnection lines IT3 to some of the first interconnection lines IT1.

The ball lands BL may be arranged on a lower surface of the third lower insulating layer OL3. The third vias VP3 may penetrate the third lower insulating layer OL3 and may connect the ball lands BL to some of the second interconnection lines IT2. External connection terminals OB may be bonded to the ball lands BL. The external connection terminals OB may include at least one of a solder ball, a conductive bump, or a conductive pillar. The external connection terminals OB may include at least one material among copper, gold, nickel, silver, and tin.

The second interconnection part 20 includes first to third inorganic insulating layers IL1 to IL3 sequentially stacked. For example, the first to third inorganic insulating layers IL1 to IL3 may each have a single-layer or multi-layer structure of at least one of silicon oxide, silicon nitride, or silicon carbon nitride. The first inorganic insulating layer IL1 may be in contact with an upper surface of the second lower insulating layer OL2. The first inorganic insulating layer IL1 may be in contact with upper surfaces and side surfaces of the third interconnection lines IT3. The first to third inorganic insulating layers IL1 to IL3 may be sequentially stacked sub-layers that are formed of a different material or different materials than that of the sequentially stacked sub-layers that form the first to third lower insulating layers OL1 to OL3. In some embodiments, the material or materials that form the first to third inorganic insulating layers IL1 to IL3 (for example core materials as opposed to added or impregnated materials) are not included in the first to third lower insulating layers OL1 to OL3, and/or the material or materials that form the first to third lower insulating layers OL1 to OL3 (for example core materials as opposed to added or impregnated materials) are not included in the first to third inorganic insulating layers IL1 to IL3.

The second interconnection part 20 may further include fourth to sixth interconnection lines IT4 to IT6, fourth to sixth vias VP4 to VP6, and first and second connection pads CP1 and CP2. The fourth to sixth interconnection lines IT4 to IT6, the fourth to sixth vias VP4 to VP6, and the first and second connection pads CP1 and CP2 may each be formed of copper, aluminum, or tungsten. In some embodiments, all of these lines, vias, and pads, are formed of the same material (e.g., one of copper, aluminum or tungsten), though the embodiments are not limited thereto. Side surfaces and lower surfaces of the fourth to sixth interconnection lines IT4 to IT6, the fourth to sixth vias VP4 to VP6, and the first and second connection pads CP1 and CP2 may be covered with a diffusion barrier layer BM. The diffusion barrier layer BM may have a single-layer or multi-layer structure of at least one of Ti, TiN, Ta, or TaN.

The fourth interconnection lines IT4 are located on the first inorganic insulating layer IL1. The fourth vias VP4 may penetrate the first inorganic insulating layer IL1 and may connect some of the fourth interconnection lines IT4 to some of the third interconnection lines IT3, respectively. The fifth and sixth interconnection lines IT5 and IT6 are located on the second inorganic insulating layer IL2. The fifth vias VP5 may penetrate the second inorganic insulating layer IL2 and may connect some of the fifth interconnection lines IT5 to some of the fourth interconnection lines IT4, respectively. The first and second connection pads CP1 and CP2 are located in the third inorganic insulating layer IL3 at an upper end of the third inorganic insulating layer IL3. Upper surfaces of the first and second connection pads CP1 and CP2 may be coplanar with an upper surface of the third inorganic insulating layer IL3. The sixth vias VP6 may penetrate the third inorganic insulating layer IL3 and may connect the first and second connection pads CP1 and CP2 to some of the fifth and sixth interconnection lines IT5 and IT6. The sixth interconnection line IT6 may connect one of the first connection pads CP1 to one of the second connection pads CP2. The sixth interconnection line IT6 may connect the first and second semiconductor devices CH1 and CH2. Since the sixth interconnection line IT6 is disposed at an upper portion of the second interconnection part 20, a signal connection distance between the first and second semiconductor devices CH1 and CH2 is decreased, and thus a signal transfer speed may be improved. The sixth signal interconnection line IT6 may directly electrically connect the first semiconductor device CH1 to the second semiconductor device CH2.

Referring to FIG. 2, in an example embodiment, a thickness of each of the lower insulating layers OL1 to OL3 may be larger than a thickness of each of the inorganic insulating layers IL1 to IL3. For example, the second lower insulating layer OL2 may have a first thickness T1, and the first inorganic insulating layer IL1 may have a second thickness T2 less than the first thickness T1. In this embodiment, a thickness, e.g., in a vertical direction perpendicular to a bottom surface of the first photo solder resist film PR1, of each of the first to third interconnection lines IT1 to IT3 that are in contact with the lower insulating layers OL1 to OL3 is larger than a thickness in the vertical direction of each of the fourth to sixth interconnection lines IT4 to IT6 that are in contact with the inorganic insulating layers IL1 to IL3. For example, the second interconnection line IT2 may have a third thickness T3, and the fifth interconnection line IT5 may have a fourth thickness T4 less than the third thickness T3.

The first and second connection pads CP1 and CP2 may each have a fifth thickness T5 less than the third thickness T3. A horizontal width of each of the first to third vias VP1 to VP3 that are in contact with the lower insulating layers OL1 to OL3 may be larger than a horizontal width of each of the fourth to sixth vias VP4 to VP6 that are in contact with the inorganic insulating layers IL1 to IL3. For example, the third via VP3 may have a first width W1 in a first horizontal direction, and the sixth via VP6 may have a second width W2 in the first horizontal direction less than the first width W1. A distance in a first horizontal direction between adjacent pads of the first connection pads CP1 or a distance in the first horizontal direction between adjacent pads of the second connection pads CP2 may be less than a distance in the first horizontal direction between adjacent lines of the third interconnection lines IT3. The distance between the adjacent pads of the first connection pads CP1 or the distance between the adjacent pads of the second connection pads CP2 may be less than a distance between adjacent ball lands of the ball lands BL. For example, a first distance DS1 in the first direction between each two adjacent pads of the first connection pads CP1 may be about 0.1 μm to about 5 μm. A surface roughness (or average roughness) Ra of an upper surface IL3_U of the third inorganic insulating layer IL3 that is located at an uppermost position among the inorganic insulating layers IL1 to IL3 may be an amount greater than 0 Å (e.g., about 0 Å) to about 10 Å. The surface roughness of the upper surface IL3_U of the third inorganic insulating layer IL3 that is located at the uppermost position among the inorganic insulating layers IL1 to IL3 may be larger than a surface roughness of a lower surface of the first photo solder resist film PR1.

The first semiconductor device CH1 includes a first chip main part 40 (e.g., chip body), a fourth inorganic insulating layer IL4 covering a lower surface of the first chip main part 40, and third connection pads CP3 arranged in the fourth inorganic insulating layer IL4. The fourth inorganic insulating layer IL4 is in contact with the third inorganic insulating layer IL3. The third connection pads CP3 are in contact with the first connection pads CP1, respectively. The fourth inorganic insulating layer IL4 may have a single-layer or multi-layer structure of at least one of silicon oxide, silicon nitride, or silicon carbon nitride. The fourth inorganic insulating layer IL4 may include the same material as the third inorganic insulating layer IL3, and a boundary surface therebetween may not be observed, for example, due to the hybrid bonding. The third connection pad CP3 may be formed of the same conductive material (e.g., copper) as the first connection pad CP1, and, in this case, a boundary surface therebetween may not be observed, for example due to the hybrid bonding. As a result, a plurality of hybrid-bonded pad structures, each including an upper pad hybrid bonded to a lower pad, may connect the first semiconductor device CH1 to the package substrate 30. The diffusion barrier layer BM may be interposed between the third connection pad CP3 and the fourth inorganic insulating layer IL4.

The second semiconductor device CH2 includes a second chip main part 50 (e.g., chip body), a fifth inorganic insulating layer IL5 covering a lower surface of the second chip main part 50, and fourth connection pads CP4 arranged in the fifth inorganic insulating layer IL5. The fifth inorganic insulating layer IL5 is in contact with the third inorganic insulating layer IL3. The fourth connection pads CP4 are in contact with the second connection pads CP2, respectively. The fifth inorganic insulating layer IL5 may have a single-layer or multi-layer structure of at least one of silicon oxide, silicon nitride, or silicon carbon nitride. The fifth inorganic insulating layer IL5 may include the same material as the third inorganic insulating layer IL3, and a boundary surface therebetween may not be observed, for example, due to the hybrid bonding. The fourth connection pads CP4 may be formed of the same conductive material (e.g., copper) as the second connection pad CP2, and, in this case, a boundary surface therebetween may not be observed. As a result, a plurality of hybrid-bonded pad structures, each including an upper pad hybrid bonded to a lower pad, may connect the second semiconductor device CH2 to the package substrate 30. The diffusion barrier layer BM may be interposed between the fourth connection pad CP4 and the fourth inorganic insulating layer IL4.

The first semiconductor device CH1 and the second semiconductor device CH2 may each be one selected from among a memory device chip such as a flash memory chip, a DRAM chip, an SRAM chip, an EEPROM chip, a PRAM chip, an MRAM chip, an ReRAM chip, a high bandwidth memory (HBM) chip, and a hybrid memory cubit (HMC) chip, a microelectromechanical system (MEMS) device chip, and an application-specific integrated circuit (ASIC) chip.

The semiconductor package 1000 according to aspects of the inventive concept does not require a separate interposer substrate between the first interconnection part 10 (corresponding to a lower substrate) and the first and second semiconductor devices CH1 and CH2, and thus an overall vertical thickness of the semiconductor package 1000 may be reduced. Furthermore, the package substrate 30 includes the second interconnection part 20 including the inorganic insulating layers IL1 to IL3 and the first and second connection pads CP1 and CP2, and thus may be bonded to the first and second semiconductor devices CH1 and CH2 using a hybrid copper bonding (HCB) method. Therefore, the overall vertical thickness of the semiconductor package 1000 may be further reduced. Furthermore, a decrease in the vertical thickness of the semiconductor package 1000 improves heat dissipation characteristics, and thus malfunction of the semiconductor package 1000 is reduced, thereby improving reliability of the semiconductor package 1000. In addition, since the HCB bonding method decreases a distance between the connection pads CP1 and CP2, pad refinement is possible. Accordingly, a highly integrated semiconductor package may be achieved.

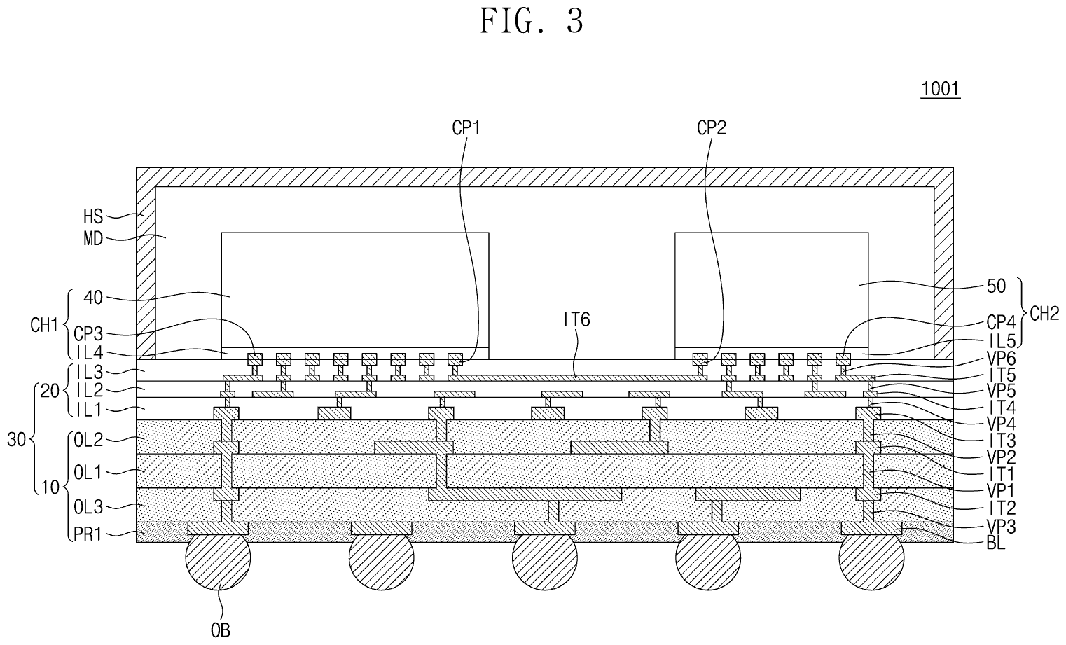

FIG. 3 is a cross-sectional view of a semiconductor package according to embodiments of the inventive concept.

Referring to FIG. 3, a semiconductor package 1001 according to the present example may have a structure in which a mold layer MD and a heat dissipation member HS are added to the structure of the semiconductor package 1000 of FIG. 1. The mold layer MD covers the first and second semiconductor devices CH1 and CH2 and the package substrate 30, and contacts top and side surfaces of the first and second semiconductor devices CH1 and CH2 and a top surface of the package substrate 30 other than where the first and second semiconductor devices CH1 and CH2 and the heat dissipation member HS are located. The mold layer MD may include an insulative resin such as an epoxy molding compound (EMC). The mold layer MD may further include a filler, which may be dispersed in the insulative resin. The heat dissipation member HS may cover an upper surface and side surface of the mold layer MD. The heat dissipation member HS may form an outer barrier or encasement, and may include a material with excellent thermal conductivity, for example, graphene or metal such as copper, tungsten, titanium, and aluminum. Other structures may be the same as those described with reference to FIGS. 1 and 2.

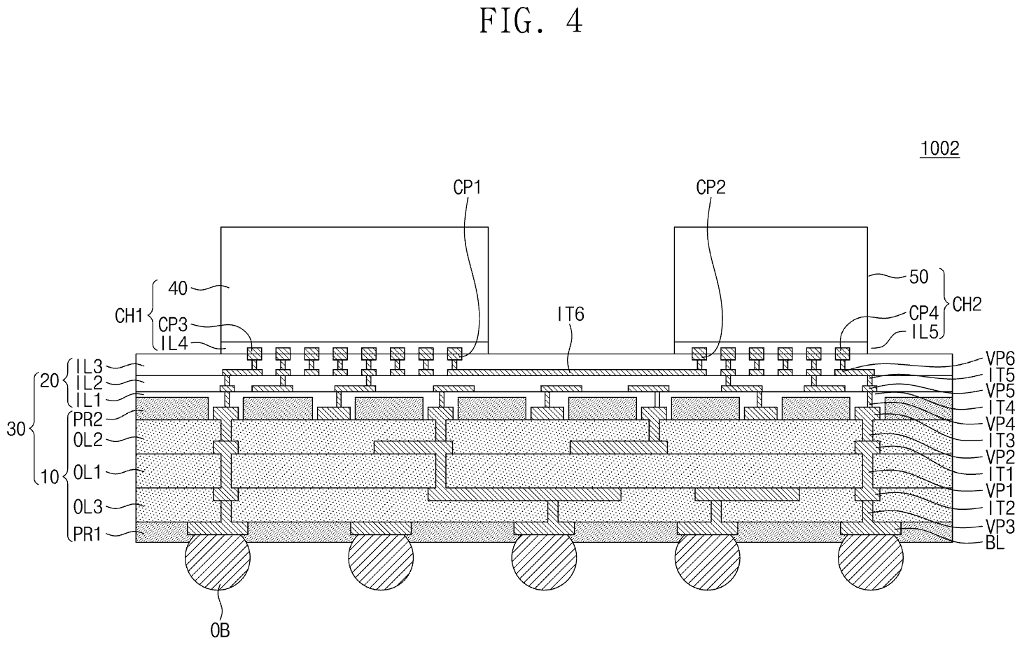

FIG. 4 is a cross-sectional view of a semiconductor package according to embodiments of the inventive concept.

Referring to FIG. 4, a semiconductor package 1002 according to the present example may have a structure in which a second photo solder resist film PR2 is added to the structure of the semiconductor package 1000 of FIG. 1. In detail, the package substrate 30 may further include the second photo solder resist film PR2 disposed on the second lower insulating layer OL2. The second photo solder resist film PR2 may include, for example, the same material as the first photo solder resist film PR1. The second photo solder resist film PR2 may be formed or embedded in the first inorganic insulating layer IL1. The second photo solder resist film PR2 may be spaced apart from the third interconnection lines IT3. The first inorganic insulating layer IL1 may be in contact with the second photo solder resist film PR2. The first inorganic insulating layer IL1 may fill spaces between the third interconnection lines IT3 and the second photo solder resist film PR2. Other structures may be the same as those described with reference to FIGS. 1 and 2.

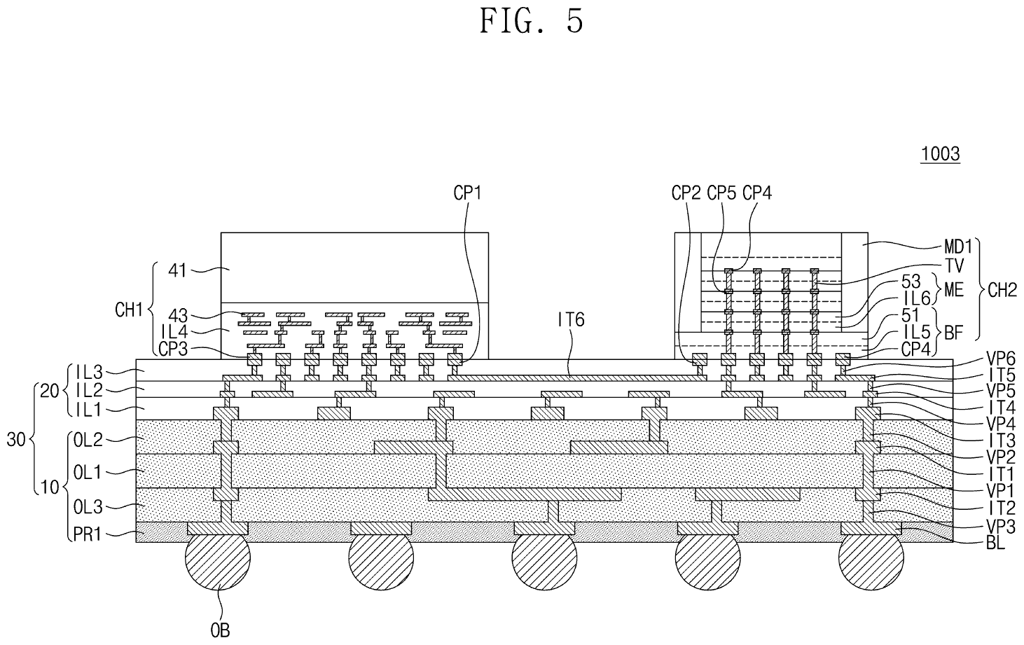

FIG. 5 is a cross-sectional view of a semiconductor package according to embodiments of the inventive concept. It should be noted that the variations described in connection with FIGS. 3-7 may be combined in various manners, such that so long as the variations do not conflict with each other, any of them may be combined. For example, the mold layer MD and a heat dissipation member HS described in FIG. 3 may be included in any of the embodiments of FIGS. 4-7; a second photo solder resist film such as PR2 of FIG. 4 may be included in any of the embodiments of FIGS. 5-7, with or without the additional features of FIG. 3, etc.

Referring to FIG. 5, in a semiconductor package 1003 according to the present example, the first semiconductor device CH1 may further include a first semiconductor substrate 41 and first chip interconnection lines 43 arranged in the fourth inorganic insulating layer IL4. The fourth inorganic insulating layer IL4 may be disposed on a lower surface of the first semiconductor substrate 41, and the third connection pads CP3 may be connected to the first chip interconnection lines 43. The first semiconductor substrate 41 may be a single-crystal silicon substrate. Although not illustrated, first transistors may be arranged on the lower surface of the first semiconductor substrate 41, and may be connected to the first chip interconnection lines 43.

The second semiconductor device CH2 may have a high bandwidth memory (HBM) chip structure. In detail, the second semiconductor device CH2 may include a buffer die BF, memory dies ME stacked on the buffer die BF, and a first mold layer MD1 covering the memory dies ME.

The buffer die BF may include a buffer substrate 51, a fifth inorganic insulating layer IL5 covering a lower surface of the buffer substrate 51, and fourth connection pads CP4 in the fifth inorganic insulating layer IL5. The buffer substrate 51 may be a semiconductor substrate. Although not illustrated, second transistors may be arranged on a lower surface of the buffer substrate 51. A first rear inorganic insulating layer (not shown) may be disposed on an upper surface of the buffer substrate 51. Buffer interconnection lines may be arranged in the fifth inorganic insulating layer IL5. The buffer die BF may further include a through-via TV penetrating the buffer substrate 51 and fifth connection pads CP5 located on the buffer substrate 51. The fifth connection pads CP5 may be arranged in the first rear inorganic insulating layer. The first rear inorganic insulating layer may be in contact with a lower surface of a sixth inorganic insulating layer IL6 of the memory die ME on the first rear inorganic insulating layer.

The memory dies ME may each include a memory substrate 53, the sixth inorganic insulating layer IL6 covering a lower surface of the memory substrate 53, and the fourth connection pads CP4 at a lower end of the sixth inorganic insulating layer IL6. The memory substrate 53 may be a semiconductor substrate. Although not illustrated, third transistors may be arranged on a lower surface of the memory substrate 53. Memory interconnection lines and data storage devices such as capacitors may be arranged in the sixth inorganic insulating layer IL6. The memory dies ME, except for the memory die ME located at an uppermost position, may each further include a through-via TV penetrating the memory substrate 53, fifth connection pads CP5 located on the memory substrate 53, and a second rear inorganic insulating layer (not shown) covering an upper surface of the memory substrate 53. The fifth connection pads CP5 may be arranged in the second rear inorganic insulating layer. The second rear inorganic insulating layer of the memory die ME disposed below may be in contact with a lower surface of the sixth inorganic insulating layer IL6 of the memory die ME on the second rear inorganic insulating layer.

The first mold layer MD1 may include an insulative resin such as an epoxy molding compound (EMC). The first mold layer MD1 may further include a filler, which may be dispersed in the insulative resin. Other structures may be the same as those described with reference to FIGS. 1 and 2.

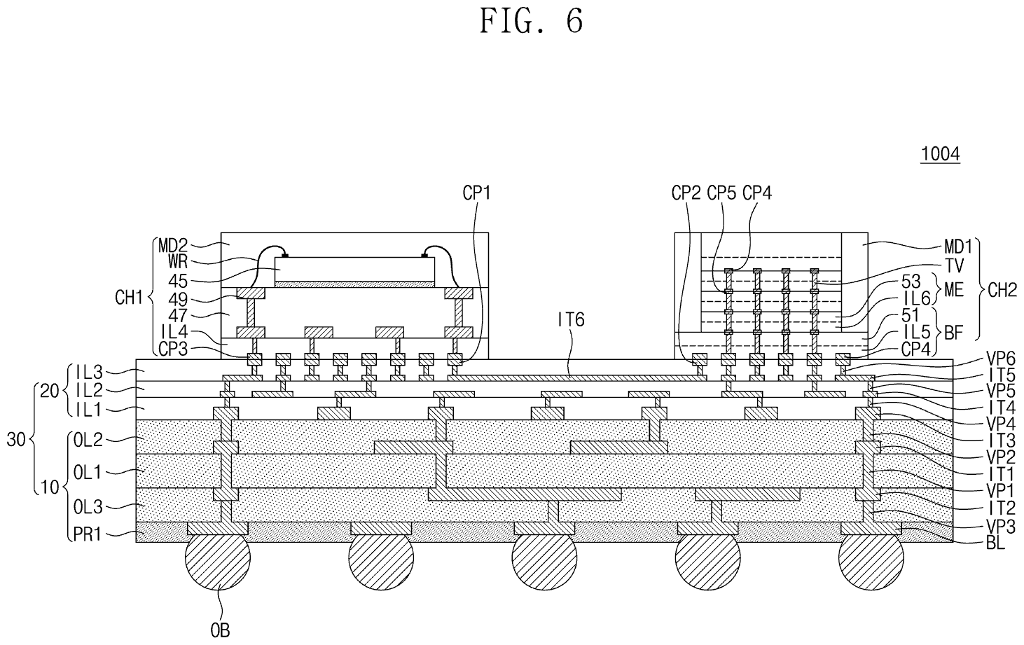

FIG. 6 is a cross-sectional view of a semiconductor package according to embodiments of the inventive concept.

Referring to FIG. 6, in a semiconductor package 1004 according to the present example, the first semiconductor device CH1 may include a chip substrate 47, a first semiconductor chip 45 disposed on the chip substrate 47, and a second mold layer MD2 covering the first semiconductor chip 45. The chip substrate 47 may be a double-sided or multi-layer printed circuit board or redistribution substrate. Conductive pads 49 may be arranged in the chip substrate 47. A lower surface of the chip substrate 47 may be covered with the fourth inorganic insulating layer IL4. The third connection pads CP3 may be arranged in the fourth inorganic insulating layer IL4. The first semiconductor chip 45 may be connected to the conductive pads 49 through a wire WR. The first semiconductor chip 45 may be one selected from among a memory device chip such as a flash memory chip, a DRAM chip, an SRAM chip, an EEPROM chip, a PRAM chip, an MRAM chip, an ReRAM chip, a high bandwidth memory (HBM) chip, and a hybrid memory cubit (HMC) chip, a microelectromechanical system (MEMS) device chip, and an application-specific integrated circuit (ASIC) chip. The second mold layer MD2 may include an insulative resin such as an epoxy molding compound (EMC). The second mold layer MD2 may further include a filler, which may be dispersed in the insulative resin. Other structures may be the same as those described with reference to FIG. 5.

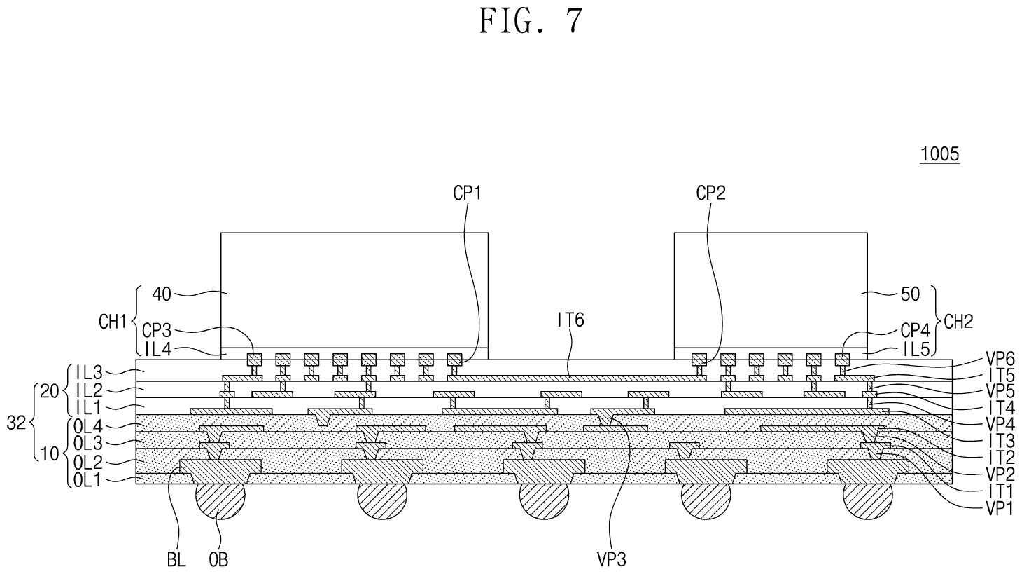

FIG. 7 is a cross-sectional view of a semiconductor package according to embodiments of the inventive concept.

Referring to FIG. 7, in a semiconductor package 1005 according to the present example, the first interconnection part 10 may have a structure of a redistribution substrate. The first interconnection part 10 includes first to fourth lower insulating layers OL1 to OL4 sequentially stacked. The first interconnection part 10 may further include the ball lands BL, the first to third interconnection lines IT1 to IT3, and the first to third vias VP1 to VP3. The first to fourth lower insulating layers OL1 to OL4 may each be a photo-imageable dielectric (PID).

A portion of the ball land BL may be located in the second lower insulating layer OL2 and another portion may penetrate the first lower insulating layer OL1. The first interconnection line IT1 may be located on the second lower insulating layer OL2, and the first via VP1 may penetrate the second lower insulating layer OL2 and may be in contact with the ball land BL. The second interconnection line IT2 may be located on the third lower insulating layer OL3, and the second via VP2 may penetrate the third lower insulating layer OL3 and may be in contact with the first interconnection line IT1. The third interconnection line IT3 may be located on the fourth lower insulating layer OL4, and the third via VP3 may penetrate the fourth lower insulating layer OL4 and may be in contact with the second interconnection line IT2. The first inorganic insulating layer IL1 is in contact with an upper surface of the fourth lower insulating layer OL4. The first inorganic insulating layer IL1 may be in contact with an upper surface and side surface of the third interconnection line IT3. Other structures may be the same as those described with reference to FIGS. 1 and 2.

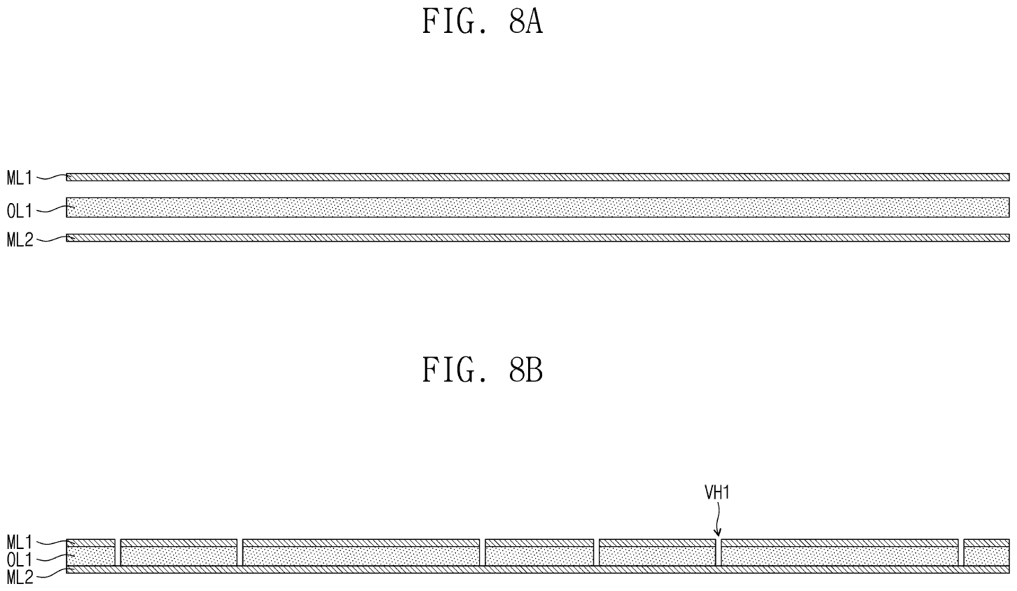

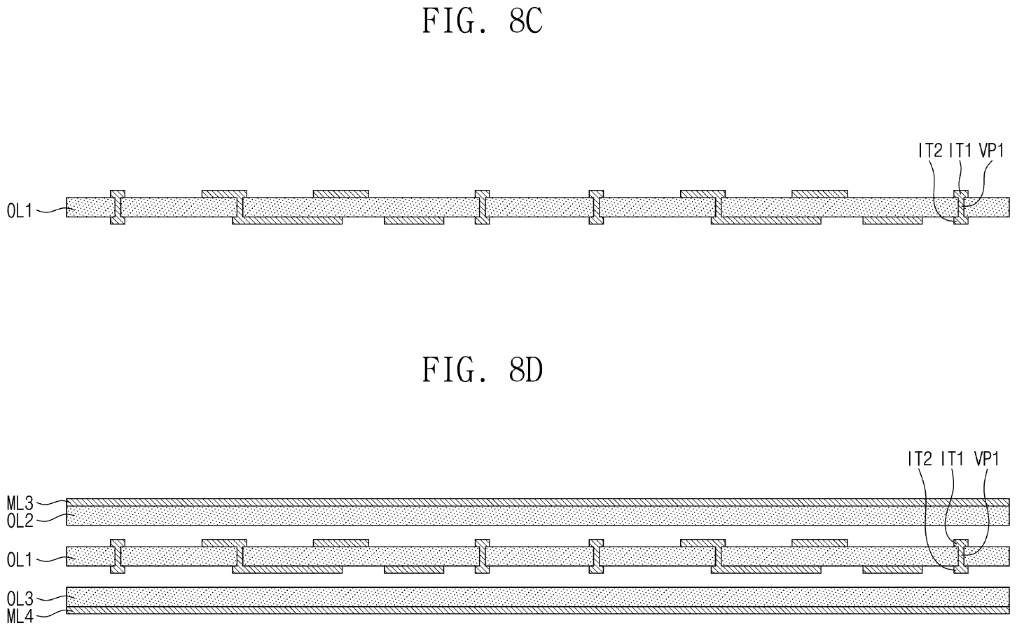

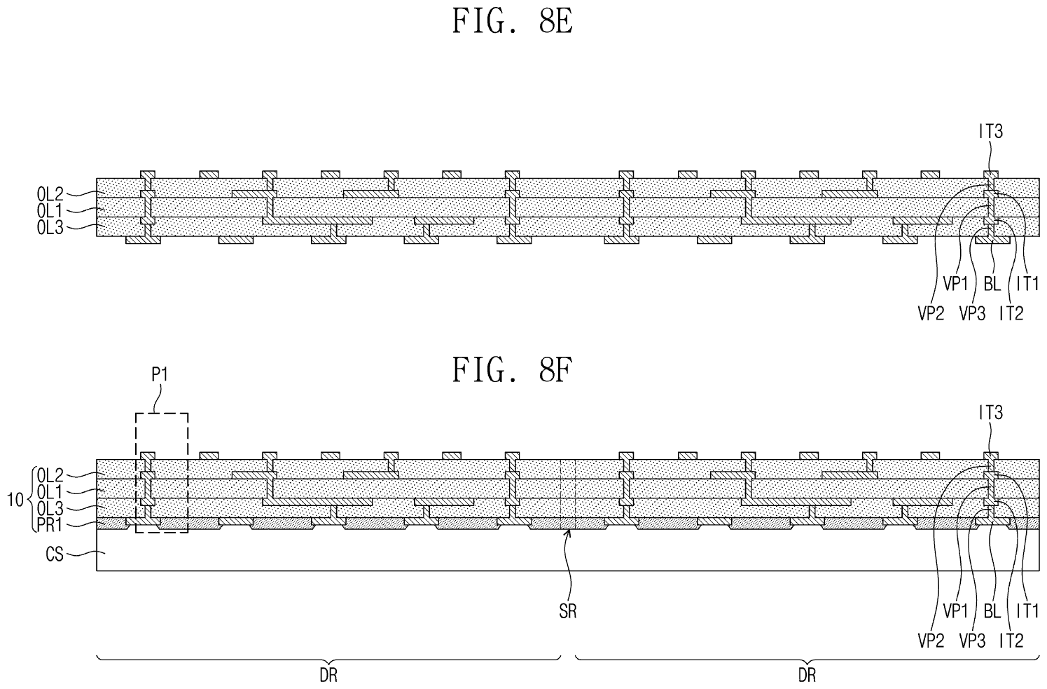

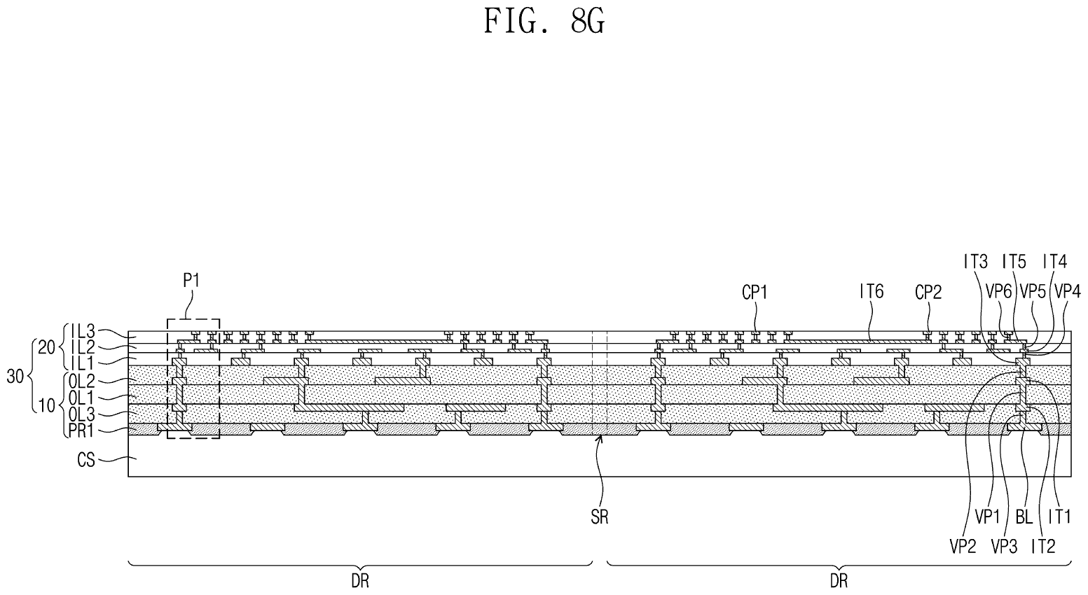

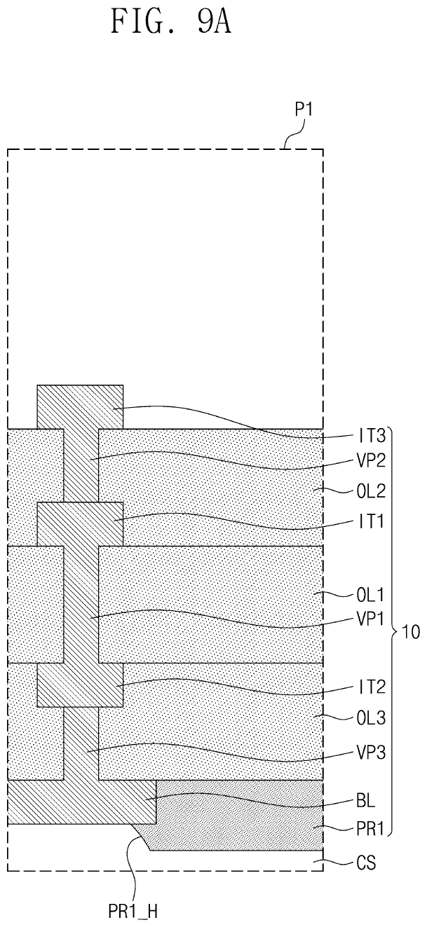

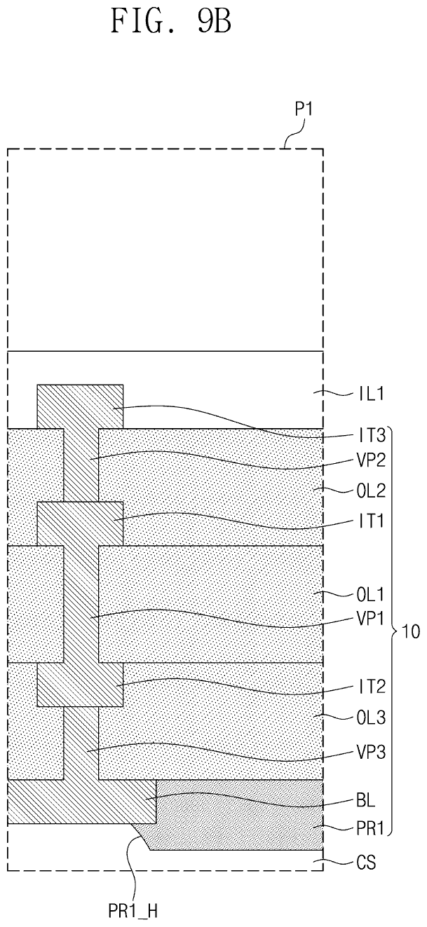

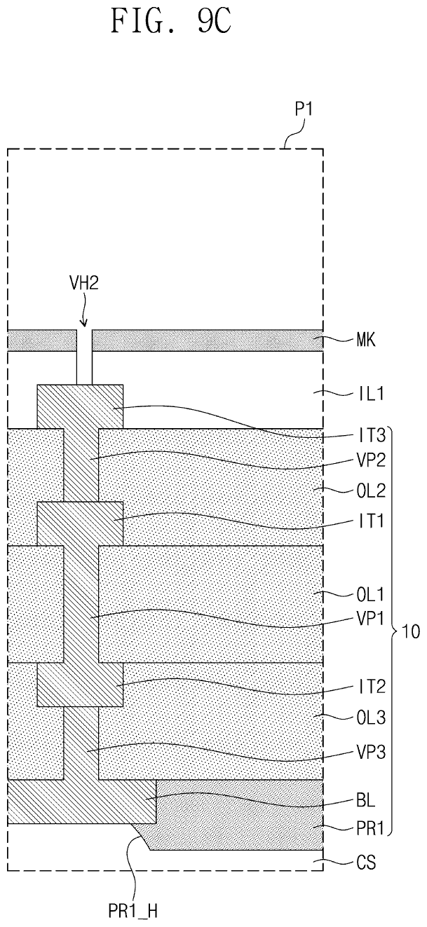

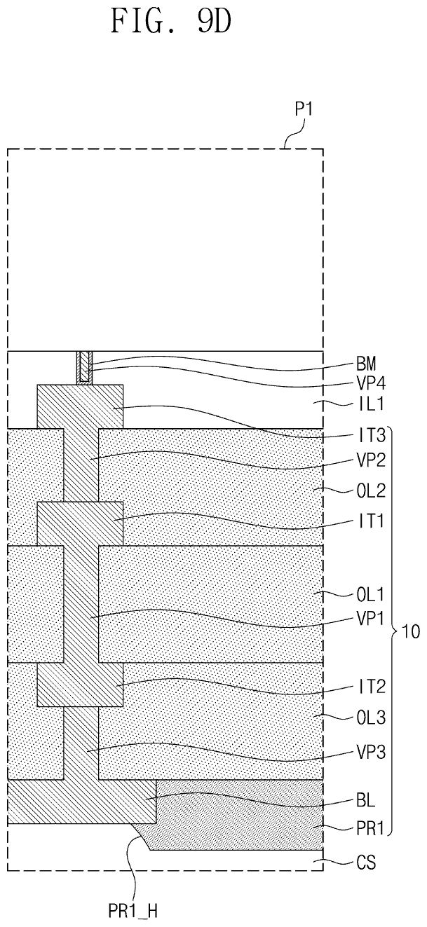

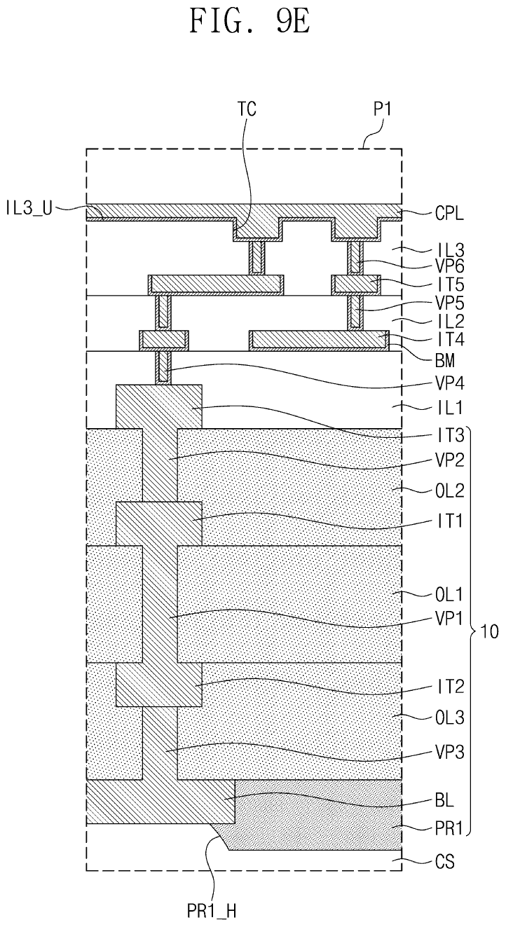

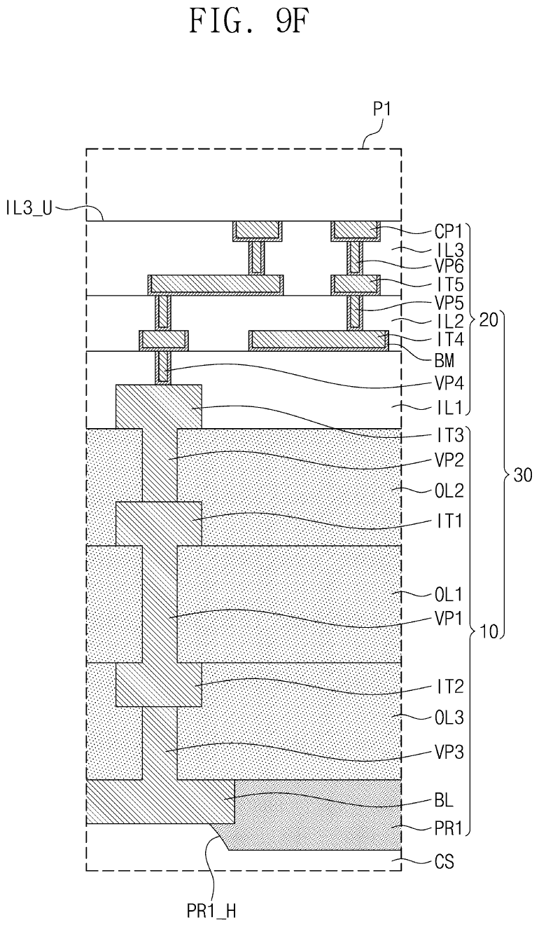

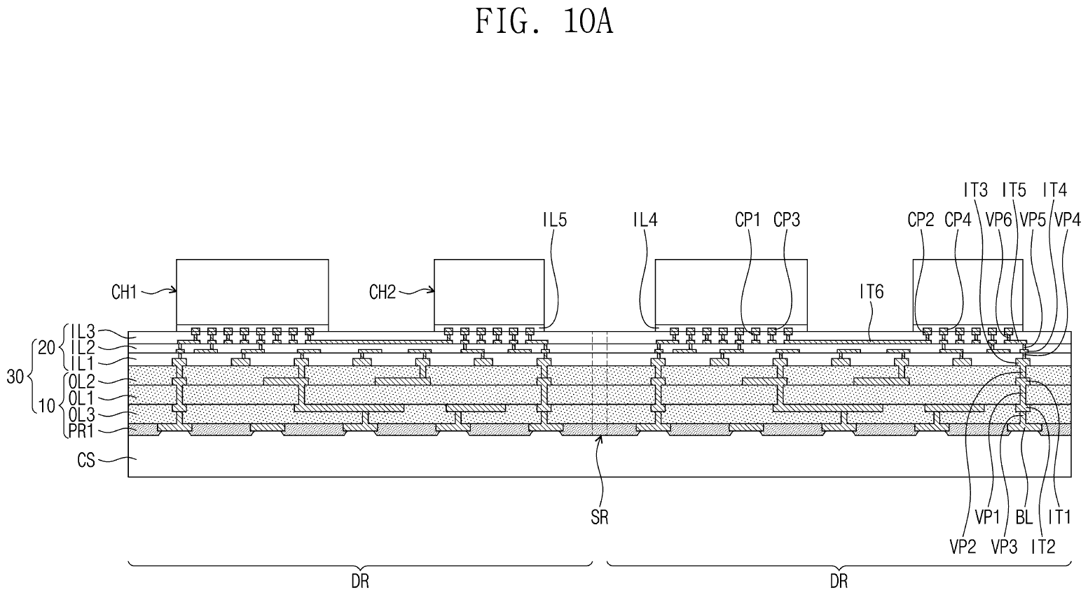

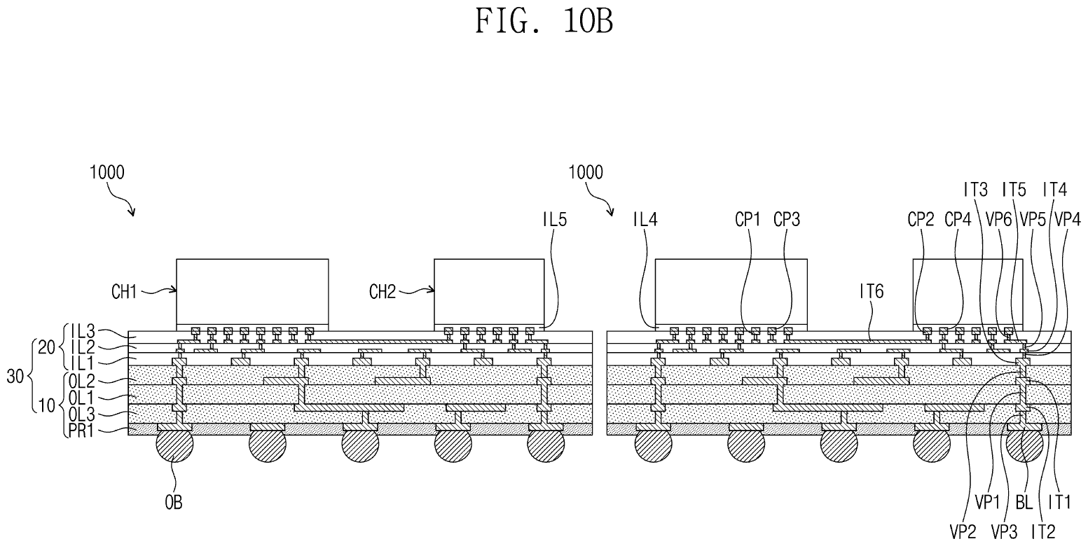

FIGS. 8A to 8G are cross-sectional views illustrating a process of manufacturing the package substrate of the semiconductor package of FIG. 1. FIGS. 9A to 9F are cross-sectional views illustrating a process of manufacturing the package substrate of the semiconductor package of FIG. 2. FIG. 9A is an example of an enlarged view of portion P1 of FIG. 8F. FIG. 9F is an example of an enlarged view of portion P1 of FIG. 8G. FIGS. 10A and 10B are cross-sectional views illustrating a process of manufacturing the semiconductor package of FIG. 1.

Referring to FIG. 8A, a laminating process is performed. For example, a first metal layer ML1 is disposed on an upper surface of the first lower insulating layer OL1, and a second metal layer ML2 is disposed on a lower surface of the first lower insulating layer OL1. The first metal layer ML1 and the second metal layer ML2 may include or be copper. The first lower insulating layer OL1 may be, for example, a prepreg in a B stage state. The first metal layer ML1 and the second metal layer ML2 are attached to the upper and lower surfaces of the first lower insulating layer OL1 while curing the first lower insulating layer OL1 by upwardly and downwardly applying pressure and heat. Here, the first lower insulating layer OL1 may be a hard prepreg.

Referring to FIG. 8B, first via holes VH1 exposing an upper surface of the second metal layer ML2 may be formed by consecutively removing the first metal layer ML1 and the first lower insulating layer OL1, for example, by performing a laser drilling process.

Referring to FIG. 8C, the first vias VP1 are formed in the first via holes VH1, respectively, by performing a plating process. Furthermore, the first interconnection lines IT1 are formed by etching the first metal layer ML1, and the second interconnection lines IT2 are formed by etching the second metal layer ML2. Accordingly, the upper and lower surfaces of the first lower insulating layer OL1 may be partially exposed.

Referring to FIGS. 8D and 8E, a laminating process is performed. The second lower insulating layer OL2 having an upper surface on which a third metal layer ML3 is formed is located on the first lower insulating layer OL1. The third lower insulating layer OL3 having a lower surface on which a fourth metal layer ML4 is formed is located under the first lower insulating layer OL1. Thereafter, the second lower insulating layer OL2 is attached to an upper surface of the first lower insulating layer OL1 and the third lower insulating layer OL3 is simultaneously attached to a lower surface of the first lower insulating layer OL1 by upwardly and downwardly applying pressure and heat. The second and third vias VP2 and VP3, the third interconnection lines IT3, and the ball lands BL are formed by performing the laser drilling process, plating process, and etching process of FIGS. 8B and 8C.

Referring to FIGS. 8F and 9A, the first photo solder resist film PR1 is formed on a lower surface of the third lower insulating layer OL3. The first photo solder resist film PR1 may be formed by performing coating, baking, exposure, and development processes on a photosensitive film. The first photo solder resist film PR1 may include openings PR1_H exposing the ball lands BL. In this manner, the first interconnection part 10 is formed. The first interconnection part 10 is attached to a carrier substrate CS. The first interconnection part 10 may include device regions DR and a separation region SR therebetween.

Referring to FIGS. 8G and 9B, the first inorganic insulating layer IL1 is formed on the second lower insulating layer OL2. The first inorganic insulating layer IL1 may be formed through a deposition process, such as atomic layer deposition (ALD) or chemical vapor deposition (CVD). The first inorganic insulating layer IL1 formed through a deposition process may have a smaller thickness than the first to third lower insulating layers OL1 to OL3 formed through a laminating process.

Referring to FIGS. 8G and 9C, a mask pattern MK is formed on the first inorganic insulating layer IL1. The mask pattern MK may be formed as a photo resist film, for example. The mask pattern MK may be formed through coating, baking, exposure, and development processes. A second via hole VH2 is formed by etching the first inorganic insulating layer IL1 using the mask pattern MK. The second via hole VH2 formed through an etching process using the mask pattern MK may have a smaller width than the first via hole VH1 formed through a laser drilling process.

Referring to FIGS. 8G and 9D, the mask pattern MK is removed. Thereafter, the diffusion barrier layer BM is deposited on the first inorganic insulating layer IL1, and a conductive layer is stacked on the diffusion barrier layer BM to fill the second via hole VH2. The conductive layer and the diffusion barrier layer BM on the first inorganic insulating layer IL1 are removed by performing a blanket anisotropic etching process or a chemical mechanical polishing (CMP) process on the conductive layer and the diffusion barrier layer BM so as to form the diffusion barrier layer BM and the fourth via VP4 in the second via hole VH2.

Referring to FIGS. 8G and 9E, the second and third inorganic insulating layers IL2 and IL3, the fifth and sixth vias VP5 and VP6, and the fourth to sixth interconnection lines IT4 to IT6 are formed by repeating the processes described above with reference to FIGS. 9B to 9D. Trenches TC are formed in an upper portion of the third inorganic insulating layer IL3. The trenches TC may expose the sixth vias VP6. The diffusion barrier layer BM is deposited on a front surface of the third inorganic insulating layer IL3, and a connection pad layer CPL is stacked on the diffusion barrier layer BM to fill the trenches TC.

Referring to FIGS. 8G and 9F, a CMP process is performed on the connection pad layer CPL and the diffusion barrier layer BM to expose the upper surface IL3_U of the third inorganic insulating layer IL3 and, at the same time, form the diffusion barrier layer BM and the first connection pads CP1 in the trenches TC. Here, the second connection pads CP2 may also be formed. Through the CMP process, the upper surface IL3_U of the third inorganic insulating layer IL3 may be formed to have a surface roughness of about 0 Å to about 10 Å. Therefore, the package substrate 30 may be manufactured by forming the second interconnection part 20 on the first interconnection part 10.

Referring to FIG. 10A, the first semiconductor device CH1 and the second semiconductor device CH2 are located in the device region DR of the package substrate 30. The first semiconductor device CH1 is formed to have the fourth inorganic insulating layer IL4 and the third connection pad CP3 on a lower surface thereof. The second semiconductor device CH2 is formed to have the fifth inorganic insulating layer IL5 and the fourth connection pad CP4 on a lower surface thereof. The first semiconductor device CH1 and the second semiconductor device CH2 are bonded to the device region DR of the package substrate 30 by performing a thermal compression process after locating the first semiconductor device CH1 and the second semiconductor device CH2 so that the third connection pad CP3 is in contact with the first connection pad CP1, the fourth connection pad CP4 is in contact with the second connection pad CP2, and the fourth inorganic insulating layer IL4 and the fifth inorganic insulating layer IL5 are in contact with the third inorganic insulating layer IL3.

Referring to FIG. 10B, the carrier substrate CS is removed from the package substrate 30. The external connection terminals OB are bonded to the ball lands BL. Thereafter, a singulation process is performed to remove the separation region SR of the package substrate 30. As a result, the semiconductor package 1000 of FIG. 1 may be manufactured.

According to a method of manufacturing a semiconductor package according to aspects of the inventive concept, an interposer substrate, for example connected using bumps, balls, or pillars, is not used, and a package substrate includes, at an upper portion thereof, a second interconnection part including inorganic insulating layers, and thus the package substrate may be bonded to semiconductor devices using an HCB method. Therefore, a manufacturing cost may be reduced, a process may be simplified, and a yield may be improved.

In a semiconductor package according to aspects of the inventive concept, a second interconnection part including inorganic insulating layers is formed at an upper portion of a package substrate, and thus semiconductor devices may be bonded using an HCB method. Therefore, since an interposer substrate, for example connected using bumps, balls, or pillars, is not required, an overall vertical thickness of the semiconductor package may be reduced. Furthermore, since the overall vertical thickness of the semiconductor package is reduced, heat dissipation characteristics are improved and malfunctions of the semiconductor package may be reduced, thereby improving the reliability of the semiconductor package. Furthermore, since a distance between connection pads may be reduced, pad refinement is possible, and thus a highly integrated semiconductor package may be achieved.

According to a method of manufacturing a semiconductor package according to aspects of the inventive concept, an interposer substrate, for example connected using bumps, balls, or pillars, is not used, and a second interconnection part including inorganic insulating layers is formed at an upper portion of a package substrate, and thus a manufacturing cost may be reduced, a process may be simplified, and a yield may be improved.

Although embodiments of the present invention have been described with reference to the accompanying drawings, those of ordinary skill in the art could easily understood that the present invention can be carried out in other specific forms without changing the technical concept or essential features. Therefore, the above embodiments should be considered illustrative and should not be construed as limiting. As described previously, the embodiments of FIGS. 1 to 7 may be combined with each other in various manners.

What is claimed is:

1. A semiconductor package comprising:
a package substrate including a first interconnection layer and a second interconnection layer sequentially stacked; and
a first semiconductor device disposed on the package substrate,
wherein the first interconnection layer includes:
first and second lower insulating layers sequentially stacked; and
a first interconnection line disposed on the second lower insulating layer,
wherein the second interconnection layer includes:
first and second inorganic insulating layers sequentially stacked; and
a first connection pad disposed in the second inorganic insulating layer, and
wherein the first semiconductor device includes:
a third inorganic insulating layer disposed at a lower end of the first semiconductor device and contacting the second inorganic insulating layer; and
a second connection pad disposed in the third inorganic insulating layer and contacting the first connection pad,
wherein the first and second lower insulating layers are formed of different materials from materials of the first and second inorganic insulating layers, and
wherein the first inorganic insulating layer is in contact with a side surface and upper surface of the first interconnection line.

2. The semiconductor package of claim 1,
wherein the first interconnection line has a first thickness in a vertical direction, and
wherein the first connection pad has a second thickness in the vertical direction less than the first thickness.

3. The semiconductor package of claim 1,
wherein the second lower insulating layer has a first thickness in a vertical direction, and
the first inorganic insulating layer has a second thickness in the vertical direction less than the first thickness.

4. The semiconductor package of claim 1,
wherein the first interconnection layer includes a first via penetrating the first lower insulating layer,
wherein the second interconnection layer includes a second via penetrating the first inorganic insulating layer,
wherein the first via has a first width in a horizontal direction, and
wherein the second via has a second width in the horizontal direction, less than the first width.

5. The semiconductor package of claim 1,
wherein the first interconnection line contacts the second lower insulating layer, and
wherein the second interconnection layer further includes a diffusion barrier layer interposed between the first connection pad and the second inorganic insulating layer.

6. The semiconductor package of claim 1,
wherein the first and second lower insulating layers are each formed of epoxy resin, thermosetting resin, polyimide, thermoplastic resin, photocurable resin, prepreg, or photo-imageable dielectric (PID), and
wherein each of the first to third inorganic insulating layers has a single-layer or multi-layer structure of at least one of silicon oxide, silicon nitride, or silicon carbon nitride.

7. The semiconductor package of claim 1, wherein each of the first and second lower insulating layers includes at least one of a glass fiber or an inorganic filler.

8. The semiconductor package of claim 1, wherein the first interconnection layer further includes a first photo solder resist film disposed under the first lower insulating layer.

9. The semiconductor package of claim 8, further comprising a second photo solder resist film disposed on the second lower insulating layer and contacting the first inorganic insulating layer.

10. The semiconductor package of claim 8, further comprising:
a second semiconductor device disposed on the package substrate and horizontally spaced apart from the first semiconductor device,
wherein the second interconnection layer further includes a third connection pad disposed in the second inorganic insulating layer and connected to the second semiconductor device and a second interconnection line connecting the first connection pad to the second connection pad.

11. The semiconductor package of claim 1, wherein the first semiconductor device includes:
a second substrate;
at least a first semiconductor die disposed on the second substrate; and
a mold layer covering the second substrate and the first semiconductor die,
wherein the third inorganic insulating layer is disposed under the second substrate.

12. The semiconductor package of claim 1,
wherein an upper surface of the second inorganic insulating layer has a surface roughness of an amount greater than 0 Å to 10 Å,
wherein the first connection pad is one of a plurality of first connection pads, and
wherein a distance between adjacent pads of the first connection pads is an amount from 0.1 μm to 5 μm.

13. The semiconductor package of claim 1, wherein:
the first interconnection layer is a lower substrate; and
the second interconnection layer is a redistribution layer on the lower substrate.

14. A semiconductor package comprising:
a lower substrate;
a redistribution layer on the lower substrate; and
a first semiconductor device and a second semiconductor device arranged on the redistribution layer and horizontally spaced apart from each other,
wherein the lower substrate includes:
first and second lower insulating layers sequentially stacked, and
a first interconnection line disposed on the second lower insulating layer,
wherein the redistribution layer includes:
first and second inorganic insulating layers sequentially stacked, and
a first connection pad and a second connection pad arranged in the second inorganic insulating layer and spaced apart from each other,
wherein the first semiconductor device includes:
a third inorganic insulating layer disposed at a lower end of the first semiconductor device and contacting the second inorganic insulating layer, and
a third connection pad disposed in the third inorganic insulating layer and contacting the first connection pad, and
wherein the second semiconductor device includes:
a fourth inorganic insulating layer disposed at a lower end of the second semiconductor device and contacting the second inorganic insulating layer, and
a fourth connection pad disposed in the fourth inorganic insulating layer and contacting the second connection pad,
wherein the first and second lower insulating layers are formed of different materials from materials of the first and second inorganic insulating layers, and
wherein the first inorganic insulating layer contacts a side surface and upper surface of the first interconnection line.

15. The semiconductor package of claim 14,
wherein the first interconnection line has a first thickness in a vertical direction, and
wherein the first connection pad has a second thickness in the vertical direction less than the first thickness.

16. The semiconductor package of claim 14,
wherein the second lower insulating layer has a first thickness in a vertical direction, and
wherein the first inorganic insulating layer has a second thickness in the vertical direction less than the first thickness.

17. The semiconductor package of claim 14,
wherein each of the first and second lower insulating layers is formed of epoxy resin, thermosetting resin, polyimide, thermoplastic resin, photocurable resin, prepreg, or photo-imageable dielectric (PID), and
wherein each of the first to third inorganic insulating layers has a single-layer or multi-layer structure of at least one of silicon oxide, silicon nitride, or silicon carbon nitride.

18. A semiconductor package comprising:
a lower substrate;
external connection terminals bonded to a lower portion of the lower substrate;
a redistribution layer on the lower substrate; and
a first semiconductor device and a second semiconductor device arranged on the redistribution layer and horizontally spaced apart from each other,
wherein the lower substrate includes:
first and second lower insulating layers sequentially stacked, and
a first interconnection line disposed on the second lower insulating layer,
wherein the redistribution layer includes:
first and second inorganic insulating layers sequentially stacked, and
a first connection pad and a second connection pad arranged in the second inorganic insulating layer and horizontally spaced apart from each other,
wherein the first semiconductor device includes:
a third inorganic insulating layer disposed at a lower end of the first semiconductor device and contacting the second inorganic insulating layer, and
a third connection pad disposed in the third inorganic insulating layer and contacting the first connection pad, and
wherein the second semiconductor device includes:
a fourth inorganic insulating layer disposed at a lower end of the second semiconductor device and contacting the second inorganic insulating layer, and
a fourth connection pad disposed in the fourth inorganic insulating layer and contacting the second connection pad,
wherein the first and second lower insulating layers are formed of different materials from materials of the first and second inorganic insulating layers,
wherein an upper surface of the second inorganic insulating layer has a surface roughness of an amount greater than 0 Å to 10 Å,
wherein the second lower insulating layer has a first vertical thickness, and
wherein the first inorganic insulating layer has a second vertical thickness less than the first vertical thickness.

19. The semiconductor package of claim 18, wherein the lower substrate further includes a first photo solder resist film disposed under the first lower insulating layer.

20. The semiconductor package of claim 19, further comprising a second photo solder resist film disposed on the second lower insulating layer and contacting the first inorganic insulating layer.
